(19) United States
(12) Patent Application Publication
(10) Pub. No.: US 2016/0173026 A1
(43) Pub. Date: Jun. 16, 2016

(54) FOLDING PHOTOVOLTAIC (PV) PANEL ASSEMBLY WITH COLLAPSIBLE STAND

(71) Applicant: ASPECT SOLAR PTE LTD., Singapore (SG)

(72) Inventors: ESMOND GOEI, BROOMFIELD, CO (US); MOK TIONG TAN, SINGAPORE (SG)

(21) Appl. No.: 14/968,212

(22) Filed: Dec. 14, 2015

Related U.S. Application Data
(60) Provisional application No. 62/091,343, filed on Dec. 12, 2014.

(51) Int. Cl. H02S 30/20; H01L 31/048

(52) U.S. Cl. CPC H02S 30/20; H01L 31/048

(57) ABSTRACT

A photovoltaic panel assembly includes a center photovoltaic panel section having at least a first and second side photovoltaic panel sections located on each side of the center photovoltaic panel section. Each of the photovoltaic panels are encased in a flexible material. The first and second photovoltaic panel sections fold over the center photovoltaic section in a closed configuration and open beside the center photovoltaic section in an open configuration. A flexible flap has a first edge connected to the first side photovoltaic panel section and a second edge removeably connected to the second side photovoltaic panel section for securing the photovoltaic panel assembly in the closed configuration. A collapsible stand supports the photovoltaic panel assembly in a upright position in the open configuration and collapses to enable storage with the photovoltaic panel assembly in the closed configuration. The collapsible stand is connected to a backside of the photovoltaic panel assembly.

### CROSS-REFERENCE TO RELATED APPLICATIONS

This application claims benefit of U.S. Provisional Application No. 62/091,343, filed Dec. 12, 2014, entitled PORTABLE FOLDING PHOTOVOLTAIC (PV) SOLAR CHARGER, WHICH CONSIST OF ONE OR MORE PV PANELS, WITH VARIOUS STANDS THAT CAN BE ATTACHED AND DETACHED OR BUILT INTO THE PANEL ASSEMBLY, AND WHICH MAY BE DEPLOYED VIA INFLATABLE POUCHES, MEMBRANES OR OTHER INFLATABLE MATERIAL OR MECHANICAL FRAMES OR DEVICES THAT ARE USED TO POSITION THE SOLAR PANEL TOWARD THE SUN (Atty. Dkt. No. ASPS-32448), the specification of which is incorporated by reference herein in its entirety.

### TECHNICAL FIELD

The present invention relates to portable chargers, and more particularly, to folding, portable solar panels with an associated collapsible stand.

### BACKGROUND

As the need for increased supplies of electrical energy to power the ever-increasing number of portable electronic devices has risen, there has been a corresponding increase in the need of new and unique electrical energy generation products for powering the electrical devices. The use of battery storage packs, electrical charging cords and other portable charging devices have been implemented to charge electrical and electronic devices. Another portable energy charging solution has been the use of various types of solar cells for generating electricity in locations where electrical power outlets may not be available. The problem with solar panels is often their size which requires a great deal of storage area that often makes them hard to transport and be easily used with portable electronic devices. Thus, there is a need for a solar cell charging apparatus that is both portable and easily deployable in a manner that will ease the use of solar cells in mobile applications of a device or in remote locations.

### SUMMARY

The present invention, as disclosed and described herein, in one aspect thereof, comprises a photovoltaic panel assembly includes a center photovoltaic panel section having at least first and second side photovoltaic panel section located on each side of the center photovoltaic panel section. Each of the photovoltaic panels are encased in a flexible material. The first and second photovoltaic panel sections fold over the center photovoltaic section in a closed configuration and open beside the center photovoltaic section in an open configuration. A flexible flap has a first edge connected to the first side photovoltaic panel section and a second edge removeably connected to the second side photovoltaic panel section for securing the photovoltaic panel assembly in the closed configuration. A collapsible stand supports the photovoltaic panel assembly in a upright position in the open configuration and collapses to enable storage with the photovoltaic panel assembly in the closed configuration. The collapsible stand is connected to a backside of the photovoltaic panel assembly.

### BRIEF DESCRIPTION OF THE DRAWINGS

For a more complete understanding, reference is now made to the following description taken in conjunction with the accompanying Drawings in which:

FIG. 1 illustrates a foldable PV panel assembly;

FIG. 2 illustrates a folded PV panel assembly with removable sling strap and handle;

FIG. 3 illustrates an inflatable stand connected to a backside of a PV panel assembly;

FIG. 4 illustrates a deflated inflatable stand detached from an associated PV panel assembly;

FIG. 5 illustrates tiedowns for a PV panel assembly and inflatable stand;

FIG. 6 illustrates a PV panel assembly and inflatable stand mounted to a wall;

FIG. 7 illustrates a PV panel assembly with a multiple angle inflatable stand;

FIG. 8 illustrates a PV panel assembly with a multiple angle inflatable stand inflated to a first deployment angle;

FIG. 9 illustrates a PV panel assembly with multiple angle inflatable stand inflated to a second deployment angle;

FIG. 10 illustrates an alternative embodiment of a PV panel assembly with an inflatable stand;

FIG. 11 illustrates the inflatable stand of FIG. 10 connected to the back of a PV assembly;

FIG. 12 illustrates the inflatable stand of FIG. 10 in a first deployment position;

FIG. 13 illustrates the inflatable stand of FIG. 10 in a second deployment position;

FIG. 14 illustrates the inflatable stand of FIG. 10 in a third deployment position;

FIG. 15 illustrates a further embodiment of a PV panel assembly with a flexible stand in a first position;

FIG. 16 illustrates the PV panel assembly of FIG. 15 with the flexible stand in a second position;

FIG. 17 illustrates an alternative embodiment of the PV panel assembly of FIG. 15 with the flexible stand in a first position;

FIG. 18 illustrates the PV panel assembly of FIG. 17 with the flexible stand in a second position;

FIG. 19 illustrates an alternative embodiment of the PV panel assembly of FIG. 15;

FIG. 20 illustrates a PV panel assembly with a flexible stand in high angle and low angle positions of deployment;

FIG. 21 illustrates a PV panel assembly with a flexible stand in first and second positions to achieve high and low angles of deployment;

FIG. 22 illustrates yet another embodiment of a PV panel assembly and stand using a locking cable; and

FIG. 23 illustrates a folded PV panel assembly and stand with a storage compartment.

### DETAILED DESCRIPTION

Referring now to the drawings, wherein like reference numbers are used herein to designate like elements throughout, the various views and embodiments of a folding photovoltaic (PV) panel assembly with collapsible stand illustrated and described, and other possible embodiments are described. The figures are not necessarily drawn to scale, and in some instances the drawings have been exaggerated and/or simplified in places for illustrative purposes only. One of ordinary skill in the art will appreciate the many possible applications and variations based on the following examples of possible embodiments so as to expand the number of panels used.

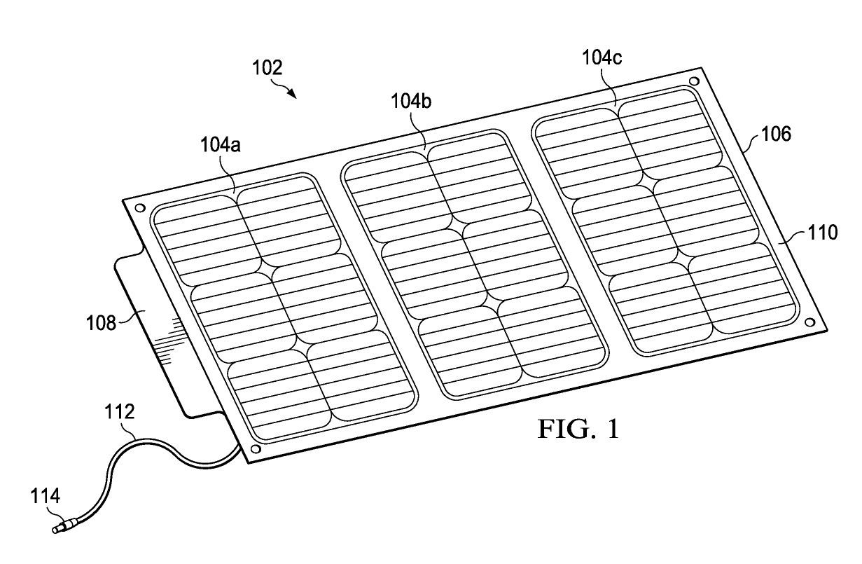

Referring now to the drawings, and more particularly to FIG. 1, there is illustrated a foldable photovoltaic (PV) panel assembly 102 in a deployed configuration. The foldable PV panel assembly 102 includes three photovoltaic (PV) panels 104 that include multiple photovoltaic cells. While an assembly 102 of three PV panels 104 is illustrated, other numbers of panels 104 may be included within the PV panel assembly. The PV panels 104 are encased in a waterproof material 106 that is flexible enabling the side panels 104A and 104C to be folded over center panel 104b. The waterproof fabric 106 also protects the PV panels 104 and encases the wiring interconnecting the PV panels 104. The assembly 102 includes a flap 108 on one edge 110 of the assembly 102 that serves a dual purpose. The flap 108 first acts as a storage compartment for the electrical cable 112 that connects to the panels 104 and second as a latching mechanism to keep the panel assembly closed when it is folded. The PV panels 104 are interconnected electrically within the waterproof fabric and the electrical cable 112 includes a DC jack connector providing a DC output to charge an external battery or electronic device connected to the DC output 114.

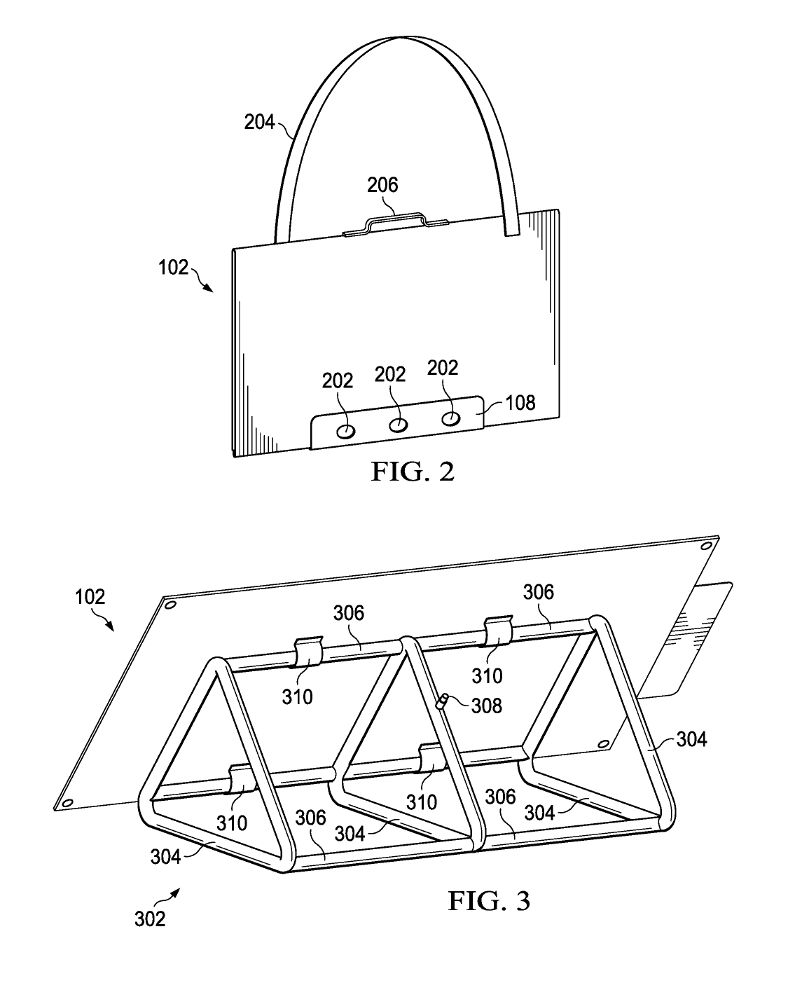

Referring now to FIG. 2, there is illustrated the PV assembly 102 in a folded configuration. The flap 108 connects to the backside of the PV panels 104 encased in a waterproof material 106 via some type of fastening mechanism 202 such as Velcro, snaps, magnets or other securing system. A carrying strap 204 and handle 206 may also be removably connected to the folded panel assembly 102 in order to provide for carrying the assembly in the folded configuration.

The ability to position the PV panels 104 such that the panels face the sun as perpendicularly as possible helps achieve maximum charging efficiency within the panels. This positioning of the PV panels 104 may be achieved by attaching the PV panel assembly 104 to a stand that easily collapses onto the folded PV assembly 102 to allow for ease of transport. A first embodiment of a collapsible support stand is illustrated in FIG. 3. In this embodiment, the PV panel assembly 102 is connected to an inflatable and foldable stand 302. The inflatable and foldable stand 302 consists of a structure including three or more triangles 304 having each of their vertices interconnected by parallel horizontal members 306. This creates a prism shaped structure for supporting the PV panel assembly 102. The inflatable and foldable stand 302 includes one or more valves 308 enabling a gas or liquid to be inserted within the stand 302 to inflate the stand for supporting the PV panel assembly 102 or for deflating the stand 302 for folding and transport of a folded PV panel assembly 102. The inflatable and foldable stand 302 is made of a waterproof, fire resistant and UL certified material such as PVC Plato, polyester nylon, etc. The inflatable and foldable stand 302 is connected to the PV panel assembly 102 using a number of holding flaps 310 that secure the horizontal members 306 to the panel assembly 102.

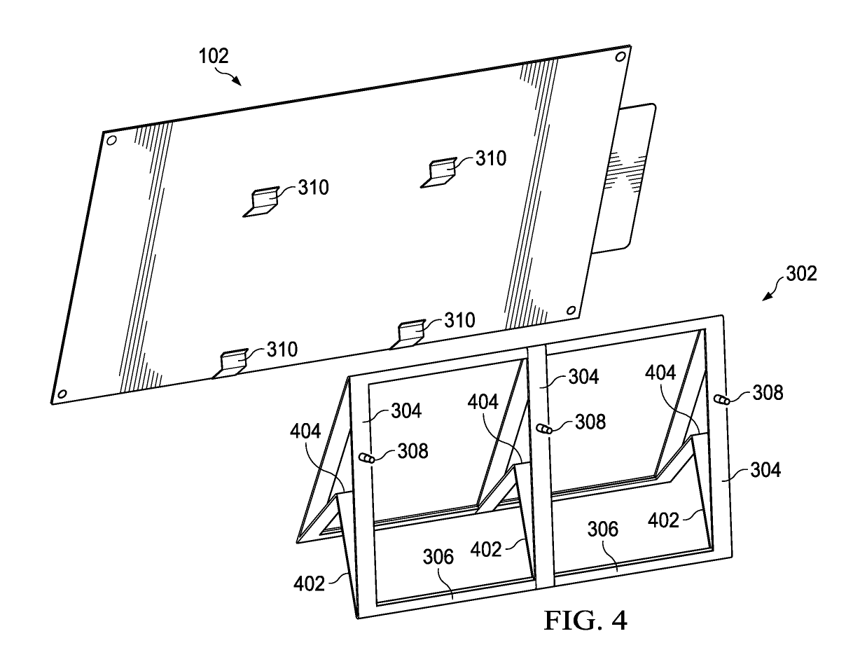

Referring now to FIG. 4, there is illustrated a deflated and detached support stand 302. The deflated stand 302 is lightweight and foldable. The stand 302 has the gas or liquid removed from its interior via the inflatable valves 308. When deflated, the base 402 of each triangle 304 may be folded along line 404 to be folded into a flat configuration. The deflated stand 302 may also be detached from the folding PV assembly 102 by opening of the holding flaps 310 and placing the deflated stand 302 within the folded PV panel assembly 102. The stand 302 may also be deflated and folded together with the PV panel assembly 102 without the need to detach it from the PV panel assembly. A gas, such as ordinary air, or a liquid, such as water, can be pumped into the stand through the valves 302. The stand may include multiple valves 302 as shown in FIG. 4 enabling the stand 302 to be split into several segments that can be individually filled with a liquid/gas to inflate the mechanical support structure.

Once the stand 302 is fully inflated, the stand provides a structural base that is strong enough to hold the PV panel assembly 102 in place. The holding flaps 310 may secure the stand 302 to the PV panel assembly 102 using Velcro, magnets, buttons, snaps, etc. The stand 302 can also be permanently fixed on the PV panel assembly 102 by stitching or via a zipper.

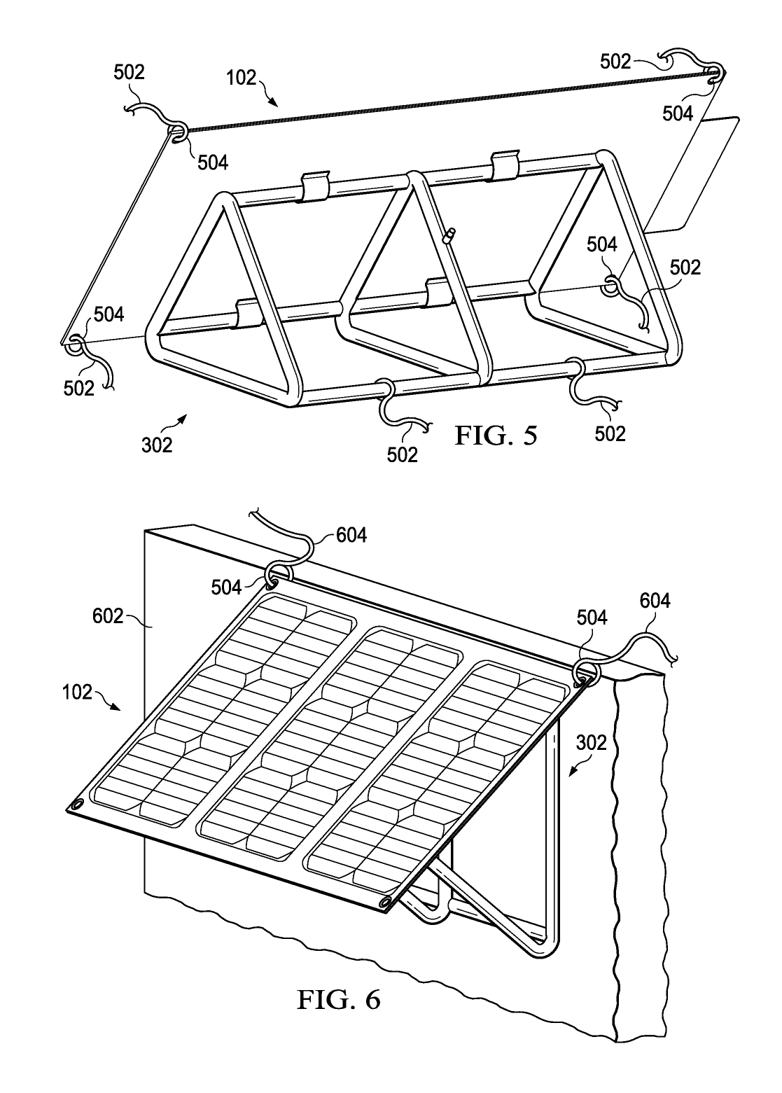

In order to improve the stability of the PV panel assembly 102 and stand 302, cords 502 or other means can be used to tie down the PV panel assembly 102 and stand 302 to the ground or supporting surface by using the four eyelet openings 504 located at the corners of the PV panel assembly 302 or by being tied directly to the stand 302 itself as illustrated in FIG. 5. Due to the light weight of the stand 302 and the PV panel assembly 102, the inflated stand can also be wall-mounted as illustrated in FIG. 6. In this case, the stand 302 supports the PV panel assembly 102 in a position outward from a wall 602, and the combined assembly is hung from the wall 602 by a pair of cords 604 connected to eyelets 504 of the PV panel assembly 102.

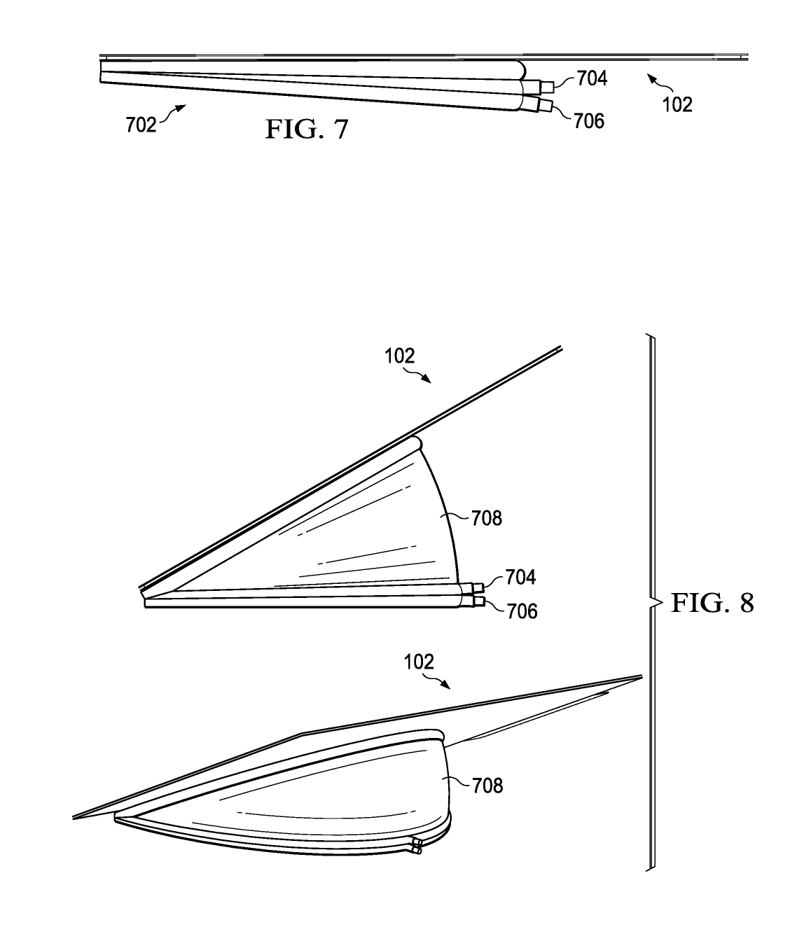

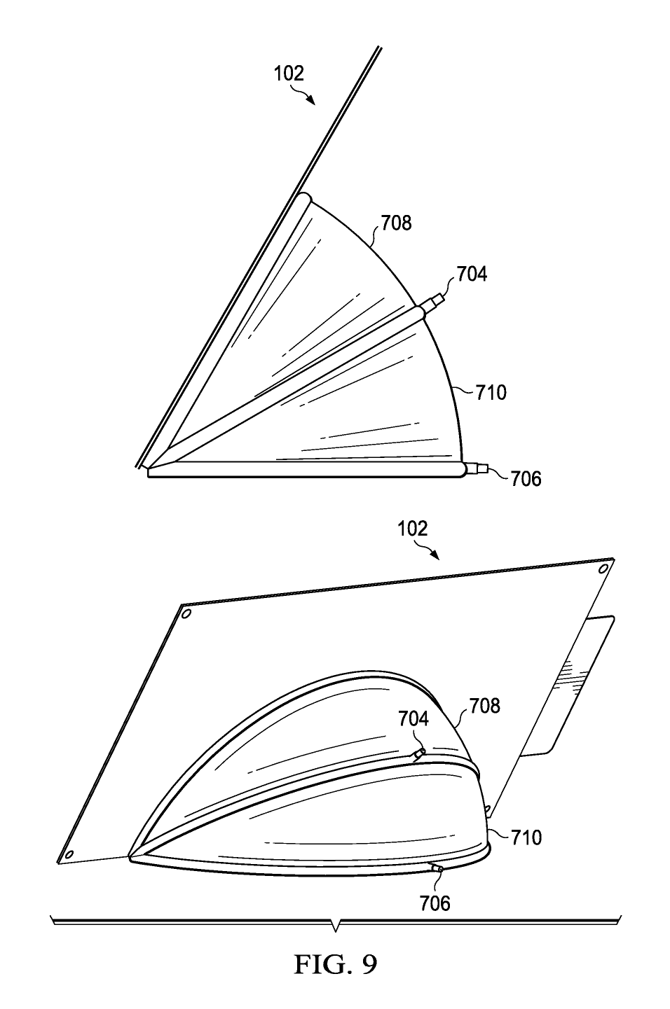

Referring now to FIGS. 7-9, there is illustrated an inflatable stand providing multiple deployment angles. FIG. 7 illustrates the PV panel assembly 102 connected to an inflatable stand 702 including two separate compartments inflatable via a first input valve 704 and a second input valve 706. Each of the separate compartments can be inflated using a gas or liquid by its respective individual input valve 704 and 706. For a low angle deployment, a first compartment 708 is inflated using input valve 704. This raises the PV panel assembly 102 to a first angle of deployment as illustrated in FIG. 8. To obtain a higher angle of deployment, a second compartment 710 is also filled with a liquid/gas through input valve 706. This places the PV panel assembly 102 at a second angle of deployment higher than the first angle of deployment as illustrated in FIG. 9. It will of course be realized by one skilled in the art that additional air compartments could be used to provide even further angle of deployment levels of the PV panel assembly 102.

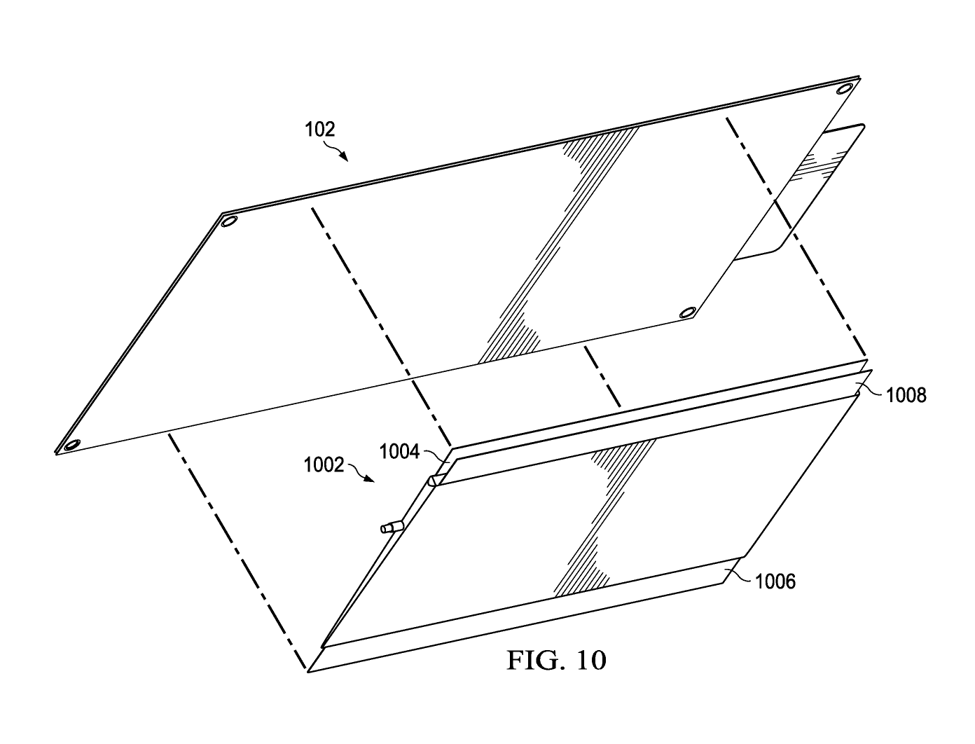

Referring now to FIGS. 10-14, there is illustrated a further embodiment of an inflatable stand enabling multiple angles of deployment by using a wedged shape inflatable stand. FIG. 10 illustrates a PV panel assembly 102 and a deflated wedge stand 1002. A series of three flaps 1004, 1006 and 1008 are included at each vertex of the wedge stand 1002. The flaps 1004, 1006 and 1008 enable connection of two of the vertices of the inflatable stand 1002 to the backside of the PV panel assembly 102 as illustrated in FIG. 11. The flaps 1004, 1006 and 1008 may connect to the back of the PV panel assembly 102 using Velcro, magnets, snaps or other types of connectors.

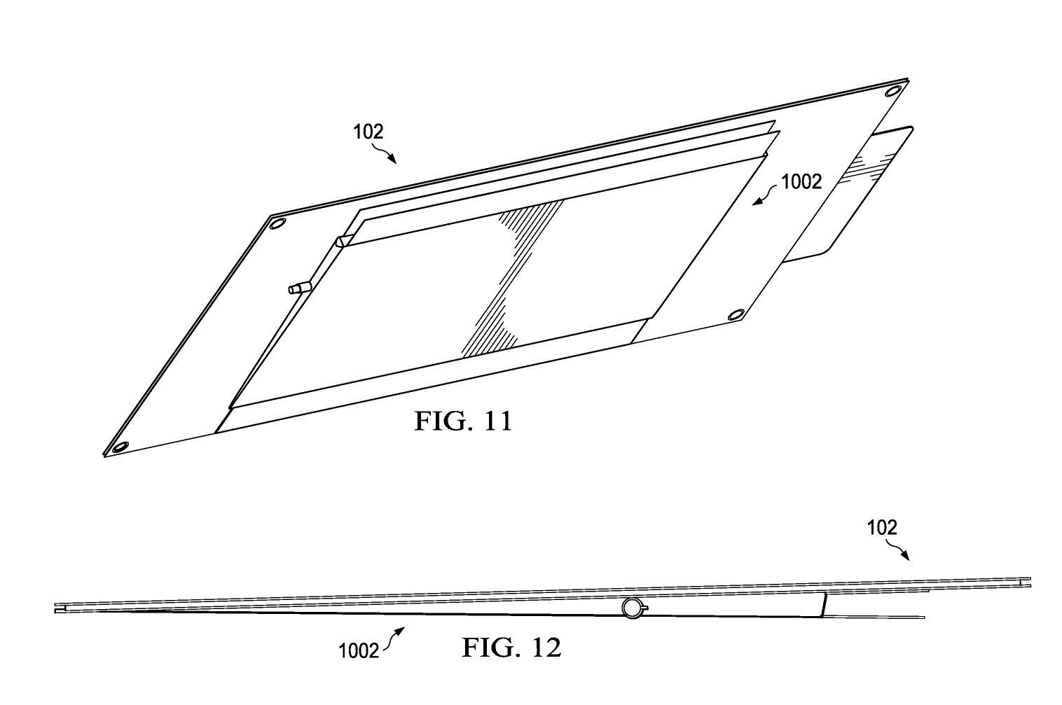

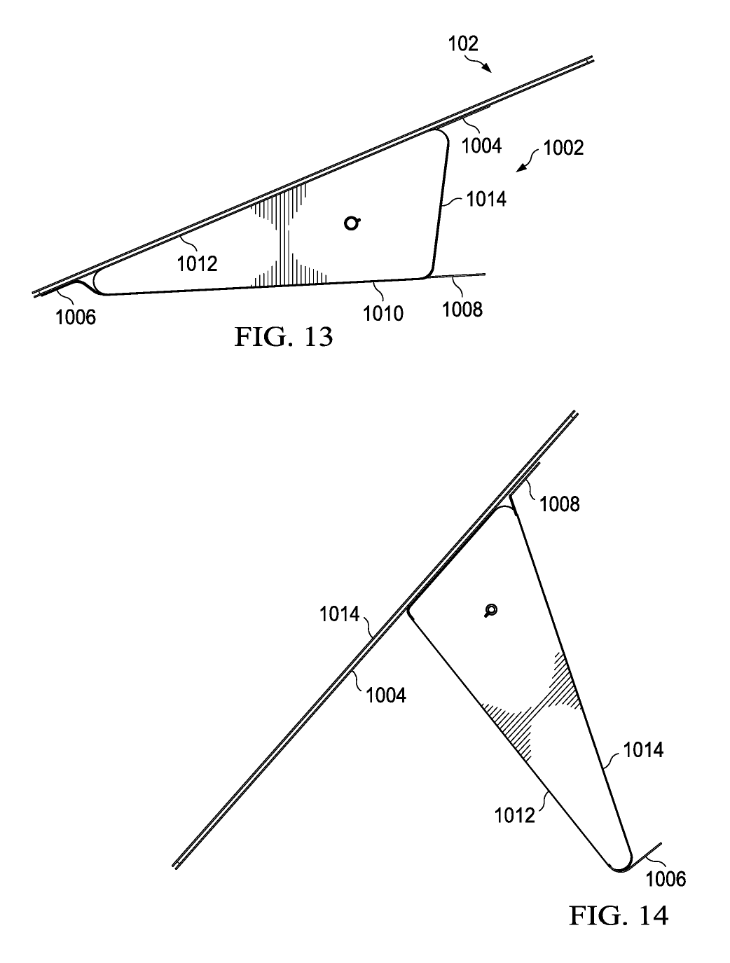

FIG. 12 illustrates a side view of the PV panel assembly 102 and deflated wedge stand 1002. This configuration provides a deployment angle of approximately 0° to 5°. To deploy the PV panel assembly 102 at a higher angle, the wedge-shaped stand 1002 may be inflated with a liquid or gas as shown in FIGS. 13 and 14. The inflated wedge-shaped stand 1002 includes three sides 1010, 1012 and 1014. Sides 1010 and 1012 comprise longer sides that are substantially longer than a shorter side 1014. By placing a longer side 1012 along the back surface of the PV panel assembly 102 and connecting the wedge stand 1002 using flaps 1004 and 1006, the PV panel assembly 102 may be placed in a lower angle position as illustrated in FIG. 13. Use of side 1010 is also possible. Side 1010 would rest upon some supporting surface in order to support the low angle position. In an alternative, higher angle configuration, side 1014 may be placed adjacent to the back of the PV panel assembly 102 by connecting flaps 1004 and 1008 to the back of the PV panel assembly as illustrated in FIG. 14. The corner connected to flap 1006 would rest on a supporting surface to support the PV panel assembly 102 in the high angle configuration. Repositioning from the low angle position illustrated in FIG. 13 to the high angle position illustrated in FIG. 14 is achieved by releasing flap 1006 from the PV panel assembly 102 and pivoting the wedge stand 1002 such that flap 1008 engages the PV panel assembly as shown in FIG. 14.

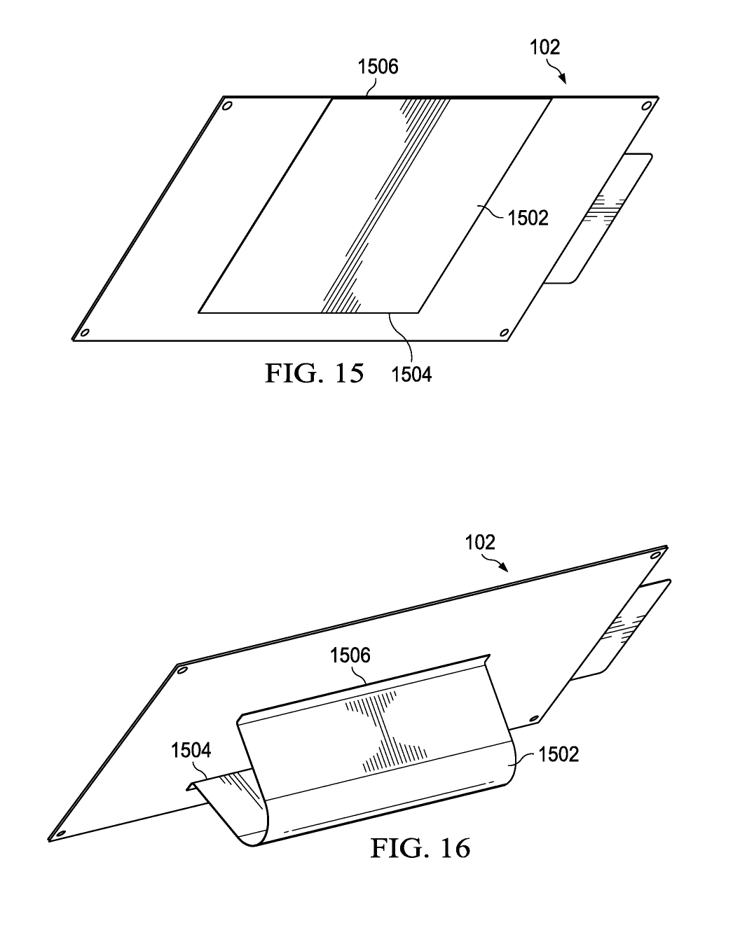

Referring now to FIG. 15, there is illustrated an alternative embodiment for a lightweight, foldable stand wherein the inflatable stand is replaced by a spring steel sheet 1502. FIG. 15 illustrates the spring steel sheet 1502 in a first collapsed configuration. The spring steel sheet 1502 is encased within a waterproof material to protect it against the weather. One edge 1504 of the spring steel sheet 1502 within the fabric is affixed to the PV panel assembly 102 by stitching while the opposite edge 1506 utilizes a different removeably connecting mechanism such as latches, magnets, Velcro, snaps etc. to hold it in place when the spring steel sheet 1502 is bent into an arc shape as illustrated in FIG. 16. FIG. 16 illustrates a second deployed configuration when the upper edge 1506 is latched into a bent configuration. A spring tension is created when the arc shaped is formed that provides the structural strength necessary to hold the PV panel assembly 102 in an upright position.

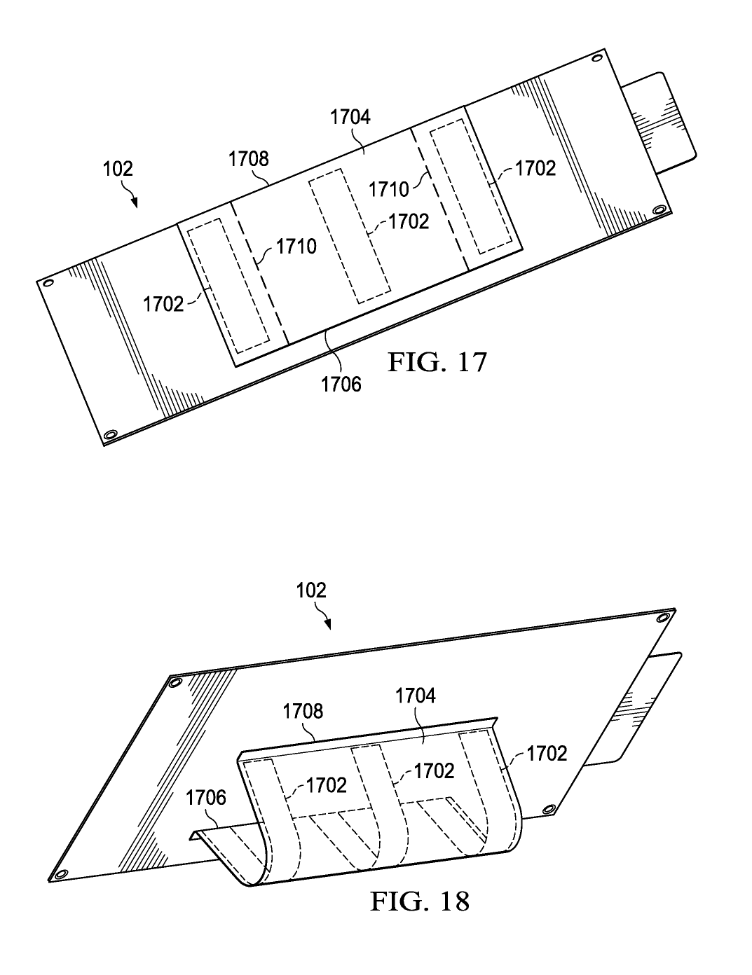

Referring now to FIGS. 17 and 18, there is illustrated an alternative embodiment of the spring steel sheet 1502 of FIG. 15. Rather than including a single spring steel sheet, a plurality of spring steel strips 1702 are encased within a waterproof fabric 1704. The strips 1702 are rectangular and are separated and parallel to each other. A first edge 1706 is connected to the PV panel assembly 102 using stitching or some other type of permanent connection, and the opposite edge 1708 is movably connected between a collapsed position as illustrated in FIG. 17 and a bent configuration as illustrated in FIG. 18 using a connecting mechanism such as latches, magnets, Velcro, snaps, etc. to hold the edge 1708 in a fixed position. The strips 1702 are placed in such a manner that they will not interfere with folding lines 1710 of the PV panel assembly 102. By placing the strips 1702 in this manner, the stand is made more foldable with respect to the PV panel assembly 102.

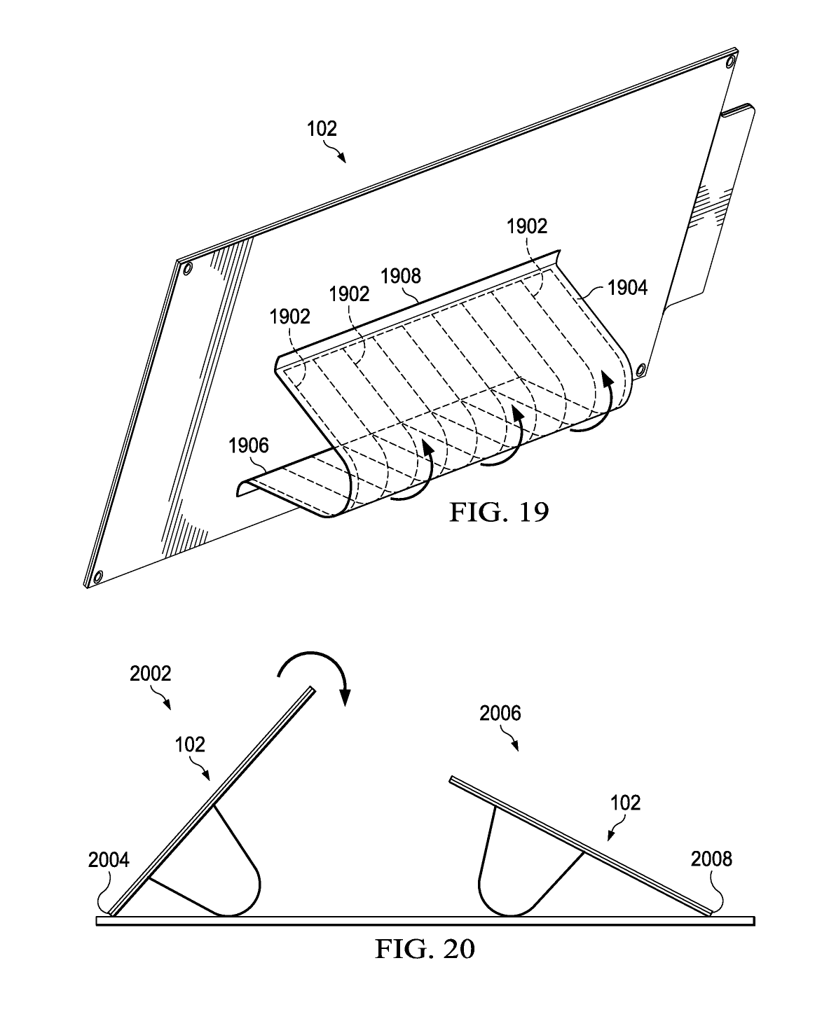

Referring now to FIG. 19, there is illustrated yet another embodiment of the spring steel sheet 1502 of FIG. 15 wherein multiple spring steel wires 1902 are encased within a waterproof fabric material 1904 parallel to each other. A first edge 1906 of the fabric material 1904 is fixedly connected to the backside of the PV panel assembly 102, and a second edge 1908 is movably connected between a collapsed and uncollapsed positions using a connector such as latches, magnets, Velcro, snaps etc. to move the edge 1908 between the collapsed and uncollapsed positions.

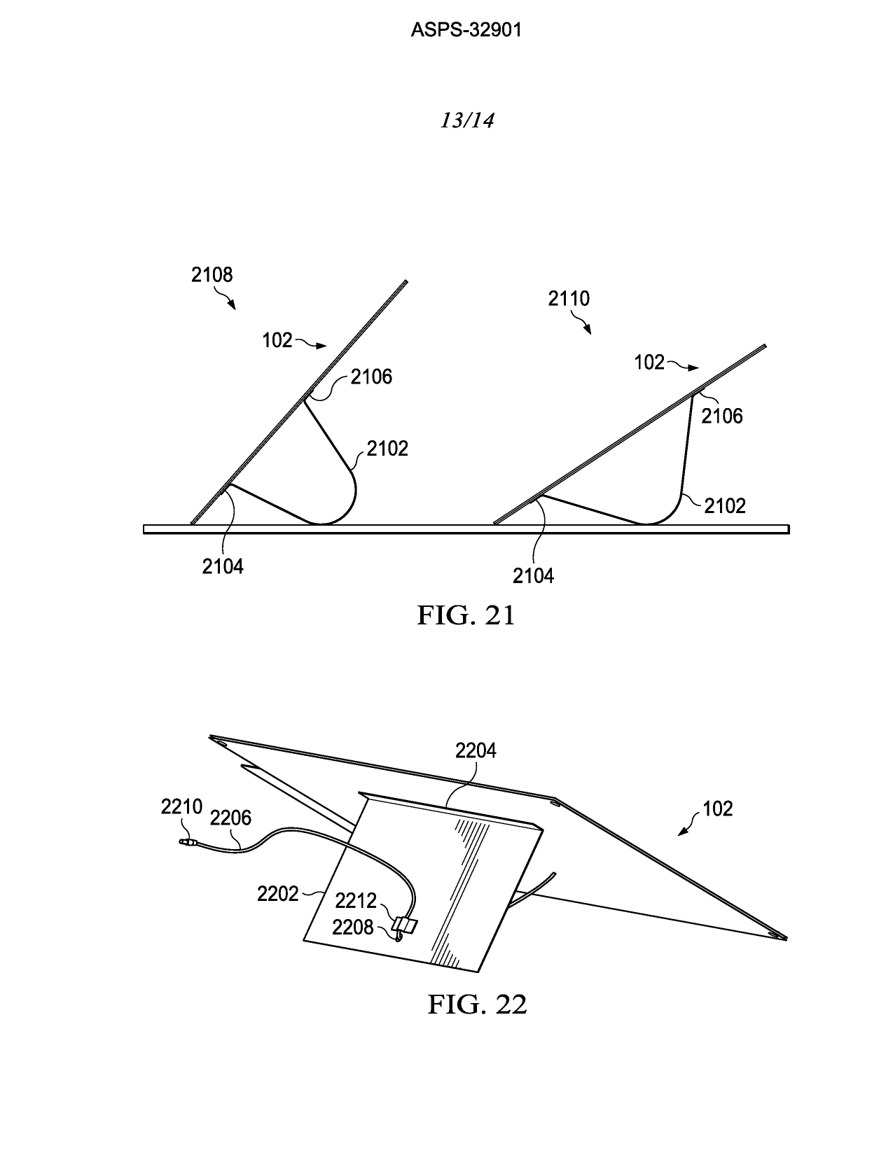

Referring now to FIG. 20, there are illustrated two deployment positions of the PV panel assembly 102 when the spring is in the un-collapsed position for any of the embodiments illustrated in FIGS. 15-19. Once the spring is deployed, the orientation of the PV panel assembly 102 to the sun can be changed by simply changing the edge of the PV panel assembly that is used as a standing edge. Thus, a high angle configuration, as illustrated generally at 2002, may be provided by placing the PV panel assembly 102 on edge 2004 and may be placed in a low angle configuration, as illustrated generally at 2006, by placing the PV panel assembly 102 on edge 2008. The angle of deployment may also be changed by altering the bending angle of the spring stand 2102 by making the spring stand 2106 to be adjustable as to where the detachable edge attaches to the back of the PV panel assembly 102 as illustrated in FIG. 21. Edge 2104 of the spring stand 2102 is fixedly connected to a permanent position on the backside of the PV panel assembly 102. Edge 2106 is movably positionable between a first location 2108 and a second location 2110 in order to change the angle of deployment of the PV panel assembly 102. When the spring stand 2102 has edge 2106 positioned at location 2108, the spring stand provides a small spring angle and high angle of deployment for the PV panel assembly 102. When the spring stand 2102 has edge 2106 positioned at location 2110, the spring stand 2102 provides a larger spring angle and lower angle of deployment for the PV panel assembly 102. This embodiment is also applicable to each of the embodiments illustrated in FIGS. 15-19.

Referring now to FIG. 22, there is illustrated a further embodiment of an adjustable stand wherein the stand 2202 comprises a rigid material such as a reinforced plastic plate having a first edge 2204 connected to the backside of the PV panel assembly 102. The stand 2202 may move from a completely closed position flush against the backside of the PV panel assembly 102 to a plurality of open positions to provide a plurality of different angle of deployments for the PV panel assembly 102. A cable 2206, that may comprise the wire cable used to connect the PV panel assembly 1022 and an external battery or electronics device, is used as a mechanism to fix the stand 2202 in place when it is deployed. The cable 2206 electrically connects to the PV panel assembly 102 and extends through a hole 2208 within the stand 2202. A connector 2210 at the end of the cable 2206 enables connection to a battery or electronic device. The cable 2206 is locked in place using a cable lock flap 2212. The cable 2210 is bent upwards and locked down in place using the cable lock flap 2212. The cable lock flap 2212 is made of a plastic material, with one end permanently affixed to the stand 2202 and the other end attachable to the standby Velcro, magnets, snaps, etc. for ease of locking and unlocking of the cable 2206. It will of course be appreciated that other types of locking mechanism such as hooks, pressure latches, etc. may also be used to lock the cable into place.

The angle of the PV panel assembly 102 is adjusted by changing the length of the locked cable. A lower deployment angle is achieved by simply extending the stand 2202 further out along the cable 2206 prior to locking it down with the cable lock flap 2212. The longer the locked cable between the stand 2202 and the PV panel assembly 102 the lower the deployment angle of the PV panel assembly. As in previous embodiments, the stand 2202 is segmented into 3 parts so that it can be folded together with the PV panel assembly 102.

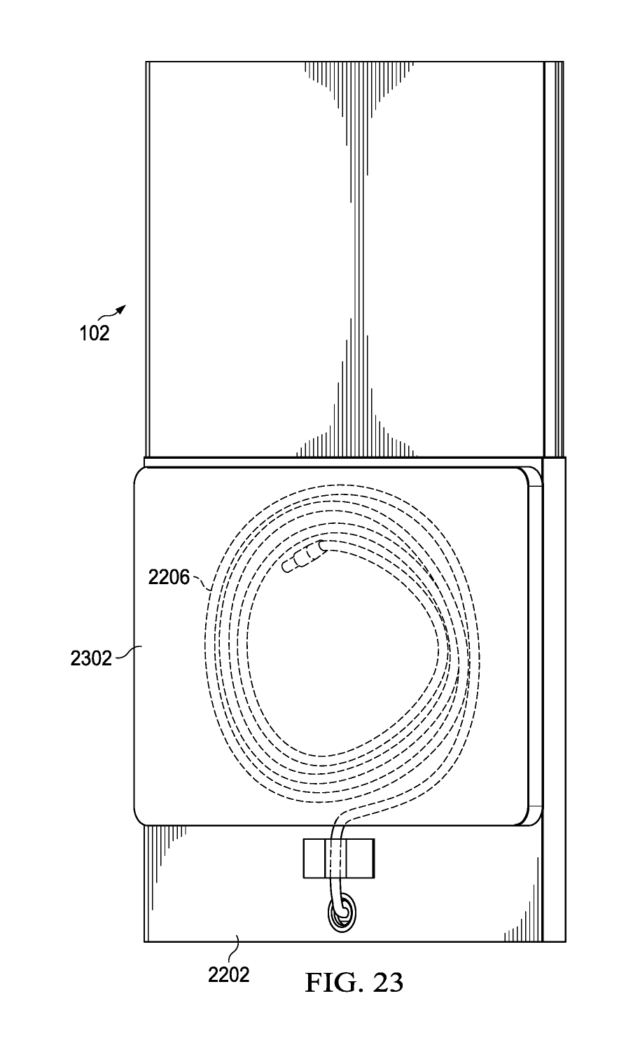

Referring now to FIG. 23 there is illustrated a folded configuration of the PV panel assembly 102 wherein a compartment 2302 is added to the stand 2202 and is used as a storage area for the cable 2206 and other accessories such as connector adapter, portable battery, etc. The opening of the compartment 2302 can be a zipper or Velcro flap.

It will be appreciated by those skilled in the art having the benefit of this disclosure that this folding photovoltaic (PV) panel assembly with collapsible stand provides a method for portably charging batteries or electronic devices. It should be understood that the drawings and detailed description herein are to be regarded in an illustrative rather than a restrictive manner, and are not intended to be limiting to the particular forms and examples disclosed. On the contrary, included are any further modifications, changes, rearrangements, substitutions, alternatives, design choices, and embodiments apparent to those of ordinary skill in the art, without departing from the spirit and scope hereof, as defined by the following claims. Thus, it is intended that the following claims be interpreted to embrace all such further modifications, changes, rearrangements, substitutions, alternatives, design choices, and embodiments.

What is claimed is:

1. An apparatus, comprising:
a photovoltaic panel assembly including a center photovoltaic panel section having at least a first and second side photovoltaic panel sections located on each side of the center photovoltaic panel section, each of the center photovoltaic panel, the first photovoltaic panel section and the second photovoltaic section encased in a flexible material;
wherein the first and second photovoltaic panel sections fold over the center photovoltaic section in a closed configuration and open beside the center photovoltaic section in an open configuration;
a flexible flap having a first edge connected to the first side photovoltaic panel section and a second edge removeably connected to the second side photovoltaic panel section, the flexible flap securing the photovoltaic panel assembly in the closed configuration; and
a collapsible stand for supporting the photovoltaic panel assembly in a upright position in the open configuration and collapsing to enable storage with the photovoltaic panel assembly in the closed configuration, the collapsible stand connecting to a backside of the photovoltaic panel assembly.

2. The apparatus of claim 1, wherein the collapsible stand comprise an inflatable stand that supports the photovoltaic panel assembly in the upright position when inflated in a first configuration and folds to a second configuration smaller than the first configuration to enable storage with the photovoltaic panel assembly when deflated.

3. The apparatus of claim 2, wherein the inflatable stand includes a plurality of separately inflatable chambers enabling positioning of the photovoltaic panel assembly in a plurality of positions.

4. The apparatus of claim 2, wherein the inflatable stand comprises a triangular shaped wedge having three sides connected to define three edges of the triangular shaped wedge, a first side of the three sides being shorter than a second side and a third side, each of the three sides including a connector for connecting a first edge and a second edge on opposite sides of the second side to the backside of the photovoltaic panel assembly in a first position and for connection the second edge and a third edge on opposite sides of the first side to the backside of the photovoltaic panel assembly in a second position.

5. The apparatus of claim 1, further including a plurality of connectors for removeably connecting the collapsible stand to the backside of the photovoltaic panel assembly.

6. The apparatus of claim 1, wherein the collapsible stand further comprises a flexible member having a first edge fixedly connected to the backside of the photovoltaic panel assembly and a second edged opposite the first edge removeably connected to at least one location on the backside of the photovoltaic panel assembly, the flexible member forming an arc between the first edge and the second edge when the second edge is connected to a first of the at least one location.

7. The apparatus of claim 6, wherein the flexible member comprises a spring steel sheet.

8. The apparatus of claim 6, wherein the flexible member comprises:
three spring steel segments, each of the segments located on the backside of one of the photovoltaic panel sections and positioned to not interfere with a folding line of the photovoltaic panel assembly; and
a fabric sleeve enclosing each of the three spring steel segments therein.

9. The apparatus of claim 6, wherein the flexible member comprises:
a plurality of spring steel wires located on the backside of the photovoltaic panel section and positioned to not interfere with a folding line of the photovoltaic panel assembly; and
a fabric sleeve enclosing each of the plurality of spring steel wires.

10. The apparatus of claim 1, wherein the collapsible stand further comprises:
a rigid plate having an edge pivotally connected to a backside of the photovoltaic panel assembly and defining a hole therein;
a cable having a first edge connected to the photovoltaic patent panel assembly that passes through the hole defined in the rigid plate;
a cable locking mechanism for locking a position of the cable with respect to the hole.

11. The apparatus of claim 1 further including a storage compartment located on the collapsible stand.

12. An apparatus, comprising:
a photovoltaic panel assembly including a center photovoltaic panel section having at least a first and second side photovoltaic panel sections located on each side of the center photovoltaic panel section, each of the center photovoltaic panel, the first photovoltaic panel section and the second photovoltaic section encased in a flexible material;
wherein the first and second photovoltaic panel sections fold over the center photovoltaic section in a closed configuration and open beside the center photovoltaic section in an open configuration;
a flexible flap having a first edge connected to the first side photovoltaic panel section and a second edge removeably connected to the second side photovoltaic panel section, the flexible flap securing the photovoltaic panel assembly in the closed configuration;
a collapsible stand for supporting the photovoltaic panel assembly in a upright position in the open configuration and collapsing to enable storage with the photovoltaic panel assembly in the closed configuration, the collapsible stand connecting to a backside of the photovoltaic panel assembly; and
a plurality of connectors for removeably connecting the collapsible stand to the backside of the photovoltaic panel assembly.

13. The apparatus of claim 12, wherein the collapsible stand comprise an inflatable stand that supports the photovoltaic panel assembly in the upright position when inflated in a first configuration and folds to a second configuration smaller than the first configuration to enable storage with the photovoltaic panel assembly when deflated.

14. The apparatus of claim 13, wherein the inflatable stand includes a plurality of separately inflatable chambers enabling positioning of the photovoltaic panel assembly in a plurality of positions.

15. The apparatus of claim 13, wherein the inflatable stand comprises a triangular shaped wedge having three sides connected to define three edges of the triangular shaped wedge, a first side of the three sides being shorter than a second side and a third side, each of the three sides including a connector for connecting a first edge and a second edge on opposite sides of the second side to the backside of the photovoltaic panel assembly in a first position and for connection the second edge and a third edge on opposite sides of the first side to the backside of the photovoltaic panel assembly in a second position.

16. The apparatus of claim 12, wherein the collapsible stand further comprises a flexible member having a first edge fixedly connected to the backside of the photovoltaic panel assembly and a second edged opposite the first edge removeably connected to at least one location on the backside of the photovoltaic panel assembly, the flexible member forming an arc between the first edge and the second edge when the second edge is connected to a first of the at least one location.

17. The apparatus of claim 16, wherein the flexible member comprises a spring steel sheet.

18. The apparatus of claim 16, wherein the flexible member comprises:
three spring steel segments, each of the segments located on the backside of one of the photovoltaic panel sections and positioned to not interfere with a folding line of the photovoltaic panel assembly; and
a fabric sleeve enclosing each of the three spring steel segments therein.

19. The apparatus of claim 16, wherein the flexible member comprises:
a plurality of spring steel wires located on the backside of the photovoltaic panel section and positioned to not interfere with a folding line of the photovoltaic panel assembly; and
a fabric sleeve enclosing each of the plurality of spring steel wires.

20. The apparatus of claim 12, wherein the collapsible stand further comprises:
a rigid plate having an edge pivotally connected to a backside of the photovoltaic panel assembly and defining a hole therein;
a cable having a first edge connected to the photovoltaic patent panel assembly that passes through the hole defined in the rigid plate;
a cable locking mechanism for locking a position of the cable with respect to the hole.

21. The apparatus of claim 12 further including a storage compartment located on the collapsible stand.
